(19) United States
(12) Patent Application Publication
(10) Pub. No.: US 2026/0247944 A1
(43) Pub. Date: Aug. 20, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/643,028

(22) Filed: Apr. 9, 2026

Related U.S. Application Data
(63) Continuation of application No. PCT/JP2023/037169, filed on Oct. 13, 2023.

(51) Int. Cl. H10W 20/42; H10D 84/85

(52) U.S. Cl. CPC H10W 20/42; H10D 84/851

(57) ABSTRACT

A semiconductor device includes: substrate; first power supply wiring and second power supply wiring formed on a first surface of the substrate; first semiconductor layer formed above a second surface of the substrate opposite the first surface and electrically connected to the first power supply wiring; second semiconductor layer formed above the second surface of the substrate and electrically connected to the second power supply wiring; third semiconductor layer formed at a position overlapping with the first semiconductor layer in a plan view; fourth semiconductor layer formed at a position overlapping with the second semiconductor layer in a plan view; first gate formed on the substrate between the first semiconductor layer and the second semiconductor layer and between the third semiconductor layer and the fourth semiconductor layer; and transistor including the first semiconductor layer, the second semiconductor layer, and the first gate.

### CROSS-REFERENCE TO RELATED APPLICATIONS

This application is a continuation application of International Application No. PCT/JP2023/037169 filed on October 13, 2023, and designated the U.S., the entire contents of which are incorporated herein by reference.

### TECHNICAL FIELD

The present invention relates to a semiconductor device.

### BACKGROUND ART

A complementary field effect transistor (CFET) technique, in which the CFET is formed by stacking transistors, is known. In a backside power delivery network (BS-PDN) which supplies a power supply potential from the back surface of a semiconductor substrate, a technique is known in which vias such as through silicon vias (TSV) are directly connected to the source and drain of a transistor. A technique is known in which a power switch circuit for controlling on/off of supply of a power supply potential is provided in a standard cell or the like.

### RELATED ART DOCUMENTS

### PATENT DOCUMENTS

Patent Document 1: U.S. Patent Application Publication No. 2023/0178435

Patent Document 2: U.S. Patent Application Publication No. 2023/0067311

Patent Document 3: U.S. Patent Application Publication No. 2022/0123023

Patent Document 4: U.S. Patent Application Publication No. 2022/0181258

Patent Document 5: International Publication No. 2020/065916

Patent Document 6: International Publication No. 2020/066797

Patent Document 7: International Publication No. 2020/217396

Patent Document 8: International Publication No. 2020/217400

Patent Document 9: U.S. Patent Application Publication No. 2021/0366902

Patent Document 10: U.S. Patent Application Publication No. 2022/0102479

Patent Document 11: U.S. Patent Application Publication No. 2021/0210600

### SUMMARY OF THE INVENTION

In one aspect of the present disclosure, a semiconductor device includes: a substrate; a first power supply wiring and a second power supply wiring formed on a first surface of the substrate; a first semiconductor layer formed above a second surface of the substrate opposite the first surface and electrically connected to the first power supply wiring; a second semiconductor layer formed above the second surface of the substrate and electrically connected to the second power supply wiring; a third semiconductor layer formed at a position overlapping with the first semiconductor layer in a plan view; a fourth semiconductor layer formed at a position overlapping with the second semiconductor layer in a plan view; a first gate formed on the substrate between the first semiconductor layer and the second semiconductor layer and between the third semiconductor layer and the fourth semiconductor layer; and a transistor including the first semiconductor layer, the second semiconductor layer, and the first gate.

### BRIEF DESCRIPTION OF THE DRAWINGS

FIG. 1 is a plan view showing an example of a layout of a semiconductor device according to a first embodiment;

FIG. 2 is a cross-sectional view showing an example of a cross-sectional structure of the semiconductor device of FIG. 1;

FIG. 3 is a circuit diagram showing an example of a circuit arranged in a block with respect to a standard cell of FIG. 1;

FIG. 4 is a circuit diagram showing an example of a power switch circuit of FIG. 3;

FIG. 5 is a perspective view showing an example of a layout of the power switch circuit and the standard cell of FIG. 3;

FIG. 6 illustrates perspective views showing examples of a method of connecting a top wiring and a wiring of a BSM1 layer formed on the back surface of a substrate;

FIG. 7 is a plan view showing an example of a plan view of the power switch circuit and the standard cell of FIG. 5 as viewed from a top-wiring side toward a substrate SUB;

FIG. 8 is a plan view showing an example of a plan view of the power switch circuit and the standard cell of FIG. 5 as viewed from a bottom wiring side toward a substrate side;

FIG. 9 is a plan view showing an example of a plan view of the BSM1 layer and BSM2 layer in a region where the power switch circuit and the standard cell of FIG. 5 are formed;

FIG. 10 is a cross-sectional view showing an example of a cross section taken along a line X1-X1‘ of FIGS. 7 to 9;

FIG. 11 is a cross-sectional view showing an example of a cross section taken along a line X2-X2' of FIGS. 7 to 9;

FIG. 12 is a cross-sectional view showing an example of a cross section taken along a line Y1-Y1' of FIGS. 7 to 9;

FIG. 13 is a perspective view showing an example of a layout of the power switch circuit and the standard cell in a second embodiment;

FIG. 14 is a plan view showing an example of a plan view of the power switch circuit and the standard cell of FIG. 13 when viewed from the top-wiring side toward the substrate SUB;

FIG. 15 is a plan view showing an example of the plan view of the power switch circuit and the standard cell of FIG. 13 when viewed from the bottom wiring side toward the substrate side;

FIG. 16 is a plan view showing an example of a plan view of the BSM1 layer and the BSM2 layer in a region where the switch transistor and the standard cell of FIG. 13 are formed;

FIG. 17 is a cross-sectional view showing an example of a cross section taken along the line X1-X1' of FIGS. 14 to 16;

FIG. 18 is a cross-sectional view showing an example of a cross section taken along the line X2-X2' of FIGS. 14 to 16; and

FIG. 19 is a cross-sectional view showing an example of a cross section taken along the line Y1-Y1' of FIGS. 14 to 16.

### DETAILED DESCRIPTION OF THE INVENTION

When a power switch circuit is formed by directly connecting a source or a drain of a CFET to a TSV, how the power switch circuit should be laid out has not been studied in detail.

It is an object of the present disclosure to appropriately lay out a power switch circuit formed by using a CFET whose source and drain are directly connected to a TSV.

Embodiments will now be described with reference to the drawings. Hereinafter, a sign indicating a signal is also used as a sign indicating a signal wiring or a signal terminal. A sign indicating a power supply potential is also used as a sign indicating a power supply wiring or a power supply terminal to which the power supply potential is supplied.

### First embodiment

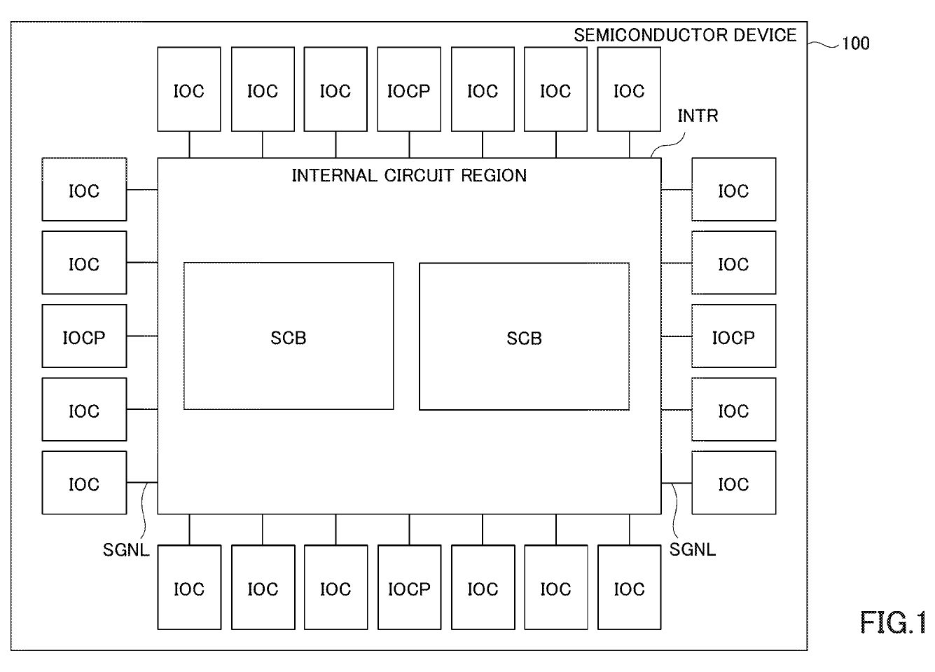

FIG. 1 shows an example of a layout of a semiconductor device according to a first embodiment. For example, a semiconductor device 100 shown in FIG. 1 may be a system on chip (SoC) or a single field-programmable gate array (FPGA).

The semiconductor device 100 includes a plurality of input/output (I/O) cells IOC and IOCP, and an internal circuit region INTR. The I/O cell IOC is an interface circuit for a signal SGNL such as an input signal, an output signal, or an input/output signal. The I/O cell IOCP is an interface circuit for a power supply potential or a ground potential.

Each of the I/O cells IOC and IOCP is connected to the internal circuit region INTR. For example, the internal circuit region INTR includes one or more standard cell blocks SCB in which standard cells are provided. In the internal circuit region INTR, logic circuits other than standard cells may be mounted, and a memory may be mounted. The memory may be mounted in the standard cell block SCB.

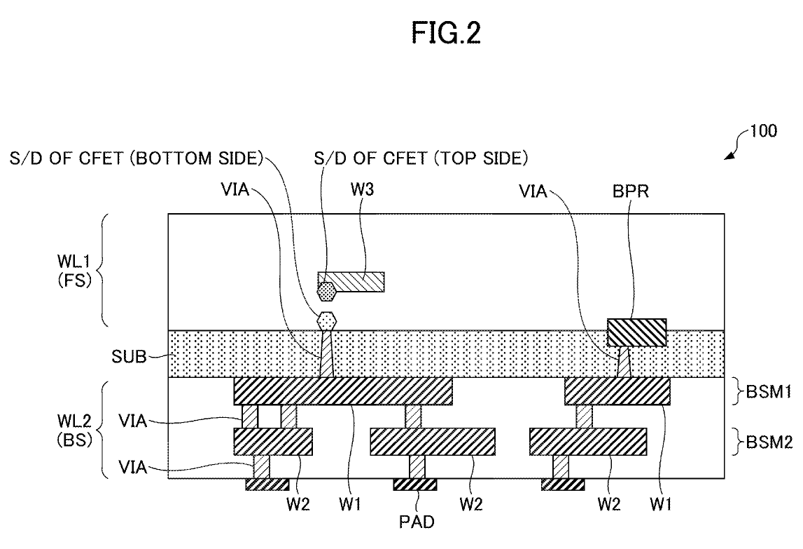

FIG. 2 shows an example of a cross-sectional structure of the semiconductor device 100 of FIG. 1. The semiconductor device 100 includes a substrate SUB, a wiring layer WL1 formed on a front surface FS side of the substrate SUB, and a wiring layer WL2 formed on a back surface BS side of the substrate SUB. The front surface FS of the substrate SUB is an example of a second surface, and the back surface BS of the substrate SUB is an example of a first surface. On the front surface FS of the substrate SUB, a source S and a drain D (hereinafter, may be inclusively indicated as "S/D"), which are parts of a CFET, are formed on a bottom side, which is a side close to the substrate SUB, and on a top side, which is a side far from the substrate SUB.

The wiring layer WL2 includes a plurality of wiring layers BSM1 and BSM2 ("BSM" stands for backside metal, and two wiring layers are shown in FIG. 2). A pad PAD serving as an external connection terminal is formed on a surface (back surface) of the wiring layer WL2 opposite to the substrate SUB. For example, wirings W1 and W2 for supplying a power supply potential, a ground potential, and the like are formed in the wiring layers BSM1 and BSM2, respectively. The wirings W1 and W2 and the wirings W2 and the pad PAD are mutually connected via a via VIA. Hereinafter, the wiring layers BSM1 and BSM2 are also referred to as a BSM1 layer or a BSM2 layer.

The wirings W1 of the wiring layer WL2 are connected to the bottom-side source S and drain D of the CFET via a via VIA such as a TSV formed in the substrate SUB. The wirings W1 may be connected to an embedded BPR (Buried Power Rail) wiring, embedded in the front surface of the substrate SUB, via a via VIA such as a TSV. Note that the wiring layer WL2 may be a wiring layer formed on the back surface of the substrate SUB or a wiring layer formed on another chip bonded to the back surface of the substrate SUB. The source S and drain D of the CFET may be connected to a wiring W3 formed in the wiring layer WL1.

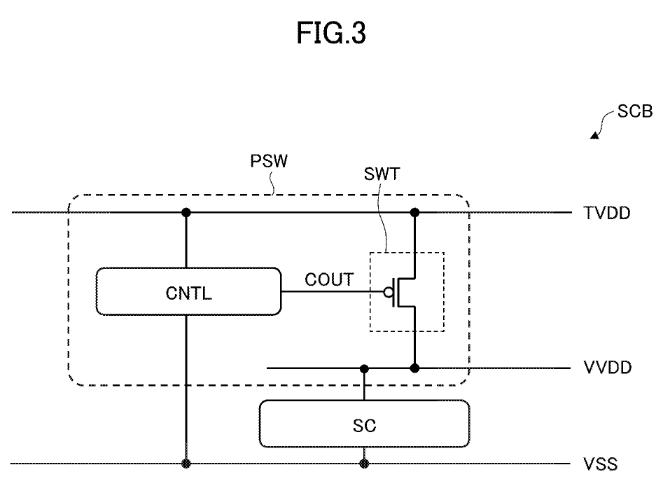

FIG. 3 shows an example of a circuit arranged in the standard cell block SCB of FIG. 1. The standard cell block SCB includes a power switch circuit PSW and a standard cell SC. The standard cell SC is connected to a virtual power supply wiring VVDD and a ground wiring VSS, and is operated by receiving a virtual power supply potential VVDD from the virtual power supply wiring VVDD. The standard cell SC includes various logic circuits.

The power switch circuit PSW operates by being connected to a power supply wiring TVDD and the ground wiring VSS. The power switch circuit PSW includes a control circuit CNTL and a switch transistor SWT. For example, the control circuit CNTL generates a control signal COUT for controlling the switch transistor SWT in accordance with an input signal (not illustrated). The power supply wiring TVDD is an example of a first power supply wiring, and the virtual power supply wiring VVDD is an example of a second power supply wiring.

The switch transistor SWT includes a PMOS transistor whose source is connected to the power supply wiring TVDD and whose drain is connected to the virtual power supply wiring VVDD, and is operated by receiving the voltage of the control signal COUT from the control circuit CNTL as a gate potential. While the switch transistor SWT is on, the power supply wiring TVDD and the virtual power supply wiring VVDD are electrically connected, and the power supply TVDD is supplied to the standard cell SC via the virtual power supply wiring VVDD. While the switch transistor SWT is off, the electrical connection between the power supply wiring TVDD and the virtual power supply wiring VVDD is interrupted, and the virtual power supply wiring VVDD is set to a floating state.

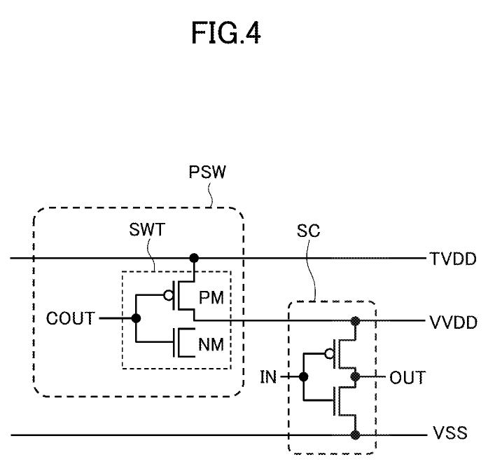

FIG. 4 shows an example of the circuit of the power switch circuit PSW of FIG. 3. The power switch circuit PSW is provided with the switch transistor SWT including a PMOS transistor PM and an NMOS transistor NM. The PMOS transistor PM has a source connected to the power supply wiring TVDD and a drain connected to the virtual power supply wiring VVDD. Both the source and the drain of the NMOS transistor NM are floating. The gates of the PMOS transistor PM and the NMOS transistor NM receive the control signal COUT output from the control circuit CNTL of FIG. 3. The source S and drain D of the NMOS transistor NM have an N-type conductivity, and the source S and drain D of the PMOS transistor PM have a P-type conductivity.

The source and drain of the NMOS transistor NM of the switch transistor SWT may be connected to the virtual power supply wiring VVDD or the ground wiring VSS. By connecting the source and drain of the transistor to a voltage wiring with a fixed potential without opening the source and drain, the potential of the source and drain of the transistor can be stabilized, and variation in the characteristics of the transistor can be suppressed. In addition, the charge/discharge current (leak current) in the source region and the drain region can be suppressed.

FIG. 4 shows an example in which the standard cell SC includes an inverter disposed between the virtual power supply wiring VVDD and the ground wiring VSS. For example, the transistors of the power switch circuit PSW and the standard cell SC are CFETs.

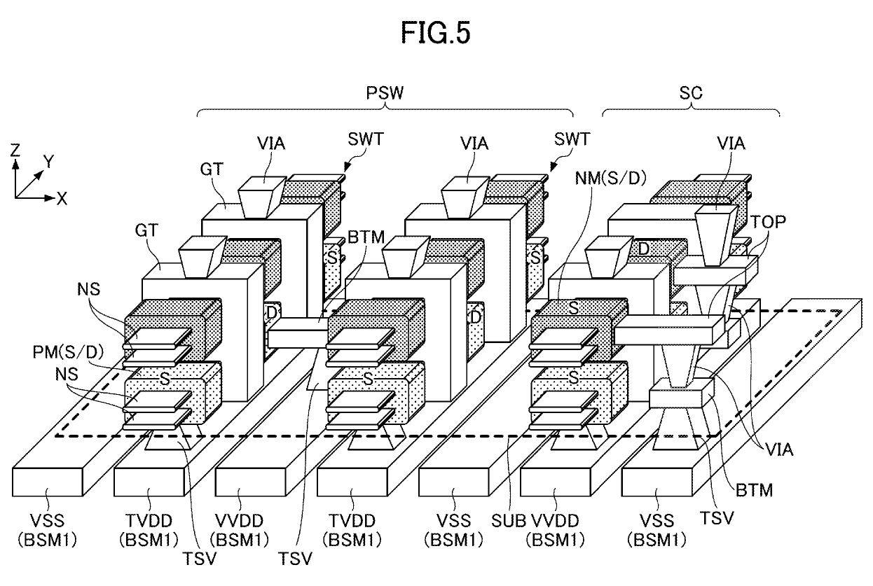

FIG. 5 shows an example of the layout of the power switch circuit PSW and the standard cell SC of FIG. 3. In FIG. 5, an interlayer insulating film is not illustrated, and the substrate SUB is simply illustrated by a thick broken line. In the layout shown in FIG. 5, the source S and drain D of the PMOS transistor PM of the CFET are formed in a bottom-side semiconductor layer disposed on the substrate SUB, and the source S and drain D of the NMOS transistor NM of the CFET are formed in a top-side semiconductor layer disposed on the bottom-side semiconductor layer. In the CFET, two bottom-side semiconductor layers are mutually connected by a bottom-side nanosheet NS, and two top-side semiconductor layers are mutually connected by a top-side nanosheet NS. In the CFET, the gate of the PMOS transistor and the gate of the NMOS transistor are common. In the present disclosure, the semiconductor layer is sometimes referred to as the source S and drain D, even when the semiconductor layer does not function as a transistor. Also, a part of the structure of the CFET, even when the semiconductor layer does not function as a transistor, is sometimes referred to as the NMOS transistor NM or the PMOS transistor PM, depending on the conductivity type of the semiconductor layer.

Signs S and D attached to the source S and drain D of the NMOS transistor NM and the PMOS transistor PM indicate the source and drain of the transistor, respectively. The source S and drain D of the NMOS transistor NM without the signs S and D indicate, for example, that the source S and drain D of the NMOS transistor NM are in an open state and do not function as transistors.

The source S of the PMOS transistor PM is an example of a first semiconductor layer, and the drain D of the PMOS transistor PM is an example of a second semiconductor layer. The source of the NMOS transistor NM is an example of one of a third semiconductor layer or a fourth semiconductor layer. The drain of the NMOS transistor NM is an example of the other of the third semiconductor layer or the fourth semiconductor layer.

In FIG. 5, in the power switch circuit PSW, a PMOS transistor group and an NMOS transistor group are arranged in the order of source, gate, drain, gate, and source in a Y-direction. As shown in FIG. 4, the source and drain of the NMOS transistors of the switch transistor SWT are in the open state.

The PMOS transistor group and the NMOS transistor group of the power switch circuit PSW are arranged at positions overlapping with the power supply wiring TVDD of the BSM1 layer in a plan view. The PMOS transistor group and the NMOS transistor group of the power switch circuit PSW are arranged at offset positions in an X-direction with respect to the virtual power supply wiring VVDD and the ground wiring VSS of the BSM1 layer in a plan view.

In the power switch circuit PSW, the source of the PMOS transistor of the switch transistor SWT is directly connected to the TSV formed below the source. The TSV is connected to a power supply wiring TVDD (BSM1) formed on the back surface of the substrate SUB. That is, the power supply potential TVDD is supplied to the source of the PMOS transistor of the switch transistor SWT by direct contact with the TSV from the back surface of the substrate SUB. The TSV connecting the source of the PMOS transistor of the switch transistor SWT to the power supply wiring TVDD (BSM1) is an example of a first via.

The drain of the PMOS transistor of the switch transistor SWT is connected to the virtual power supply wiring VVDD (BSM1) formed on the back surface of the substrate SUB via bottom wirings BTM extending in the X-direction and TSV. The bottom wiring BTM and the transistor on the bottom side of the CFET have portions at the same positions in a Z-direction.

In the standard cell SC, the source of the NMOS transistor is connected to the ground wiring VSS (BSM1) formed on the back surface of the substrate SUB via a top wiring TOP, the via VIA, bottom wirings BTM extending in the X-direction and TSV. In the standard cell SC, the drain of the NMOS transistor is connected to an upper layer wiring (not illustrated) via a top wiring TOP extending in the X-direction and a via VIA. In the standard cell SC, the drain of the NMOS transistor is connected to the bottom wiring BTM via the via VIA. The top wiring TOP and the transistor on the top side of the CFET have the same position in the Z-direction.

In the standard cell SC, the source of the PMOS transistor is directly connected to the TSV formed below the source. The TSV is connected to the virtual power supply wiring VVDD (BSM1) formed on the back surface of the substrate SUB. In the standard cell SC, the drain of the PMOS transistor is connected to the top wiring TOP via the bottom wiring BTM extending in the X-direction and the via VIA. In the PMOS transistor and the NMOS transistor of the standard cell SC, the gate and the source on the rear side in the Y-direction in FIG. 5 are set to an open state and are not used.

In the switch transistor SWT and the standard cell SC, a gate GT of each transistor is connected to an upper wiring (not illustrated) via the via VIA formed on the gate GT. The gate GT of the switch transistor SWT is an example of the first gate.

FIG. 5 shows an example in which the power supply wiring TVDD (BSM1) is disposed below the switch transistor SWT and the virtual power supply wiring VVDD (BSM1) is disposed below the switch transistor SWT at an offset position in the X-direction in a plan view. However, the virtual power supply wiring VVDD (BSM1) may be disposed below the switch transistor SWT and the power supply wiring TVDD (BSM1) may be disposed below the switch transistor SWT at an offset position in the X-direction in a plan view.

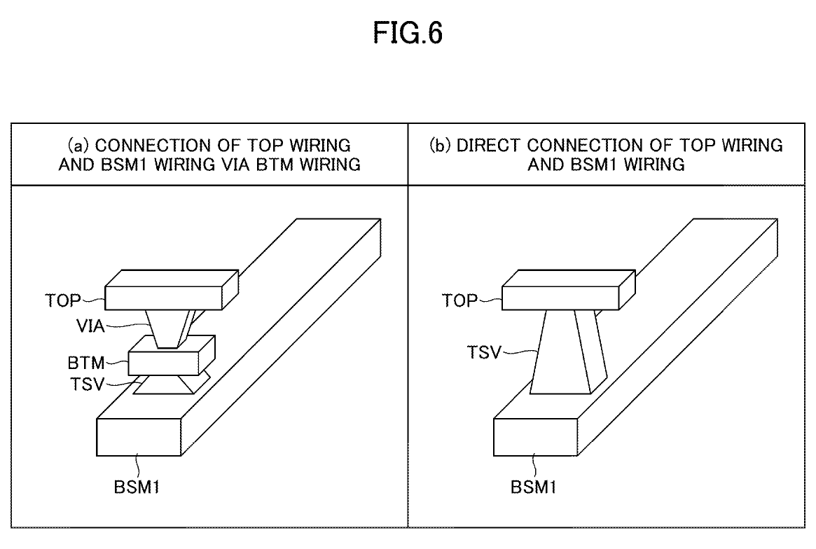

FIG. 6 shows an example of a connection method between the top wiring TOP and the wiring of the BSM1 layer formed on the back surface of the substrate. As shown in (a) of FIG. 6, the top wiring TOP and the wiring of the BSM1 layer may be connected via the bottom wiring BTM in the same manner as the wiring of the standard cell SC in FIG. 5. As shown in (b) of FIG. 6, the top wiring TOP and the wiring of the BSM1 layer may be directly connected via the TSV without passing through the bottom wiring BTM. Note that the wiring method of (b) of FIG. 6 may be applied to other embodiments.

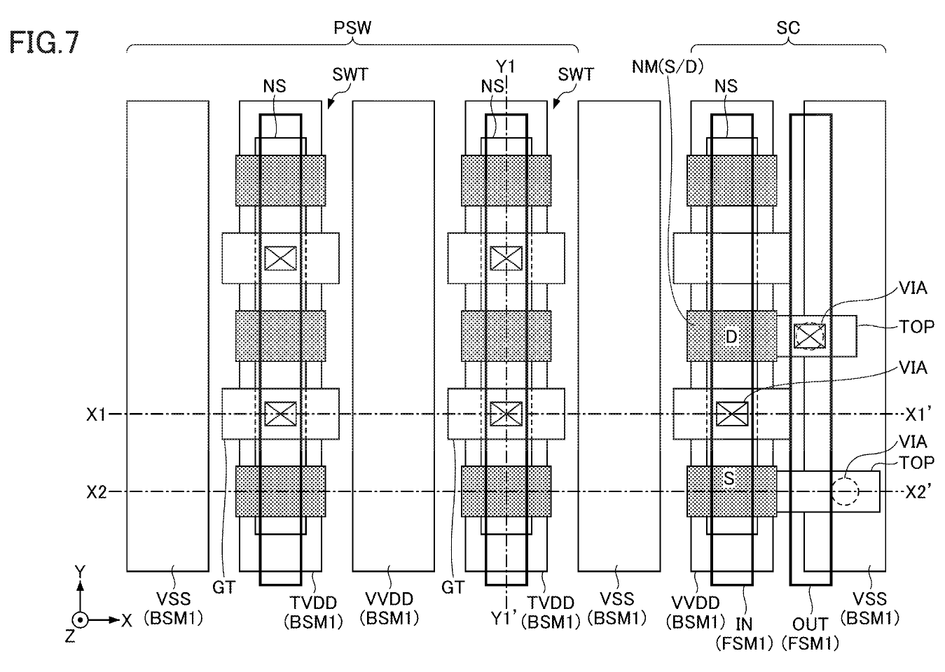

FIG. 7 shows an example of a plan view of the power switch circuit PSW and the standard cell SC of FIG. 5 as viewed from the top wiring TOP side toward the substrate SUB side. In FIG. 7, the source or drain S/D of the NMOS transistor NM not designated by any of S and D is in the open state, indicating that it does not function as a transistor.

Wirings shown by a thick solid line extending in the Y-direction indicate wirings of a wiring layer FSM1 ("FSM" stands for frontside metal) disposed on the upper side of the switch transistor SWT and the standard cell SC (the side toward the position where the CFET is disposed from the substrate SUB in the Z-direction). Wirings of the wiring layer FSM1 are located on the upper side of the top wiring TOP.

The NMOS transistor NM of the switch transistor SWT of the power switch circuit PSW is disposed at a position overlapping with the power supply wiring TVDD of the BSM1 layer in a plan view. The NMOS transistor NM of the standard cell SC is disposed at a position overlapping with the virtual power supply wiring VVDD of the BSM1 layer in a plan view.

The source and drain of the NMOS transistor NM are disposed at positions corresponding to the formation region of the top wiring TOP in the Z-direction. The source and drain of the NMOS transistor NM are arranged on both sides in the Y-direction with the gate GT between the source and drain.

When an inverter is formed in the standard cell SC, the drain D of the NMOS transistor NM of the inverter is connected to an output signal wiring OUT of the wiring layer FSM1 via the top wiring TOP and the via VIA. Hereinafter, the wiring layer FSM1 is also referred to as an FSM1 layer. The source S of the NMOS transistor NM of the inverter is connected to the via VIA on the bottom wiring BTM side via the top wiring TOP. The gate of the inverter is connected to an input signal wiring IN of the FSM1 layer via the via VIA.

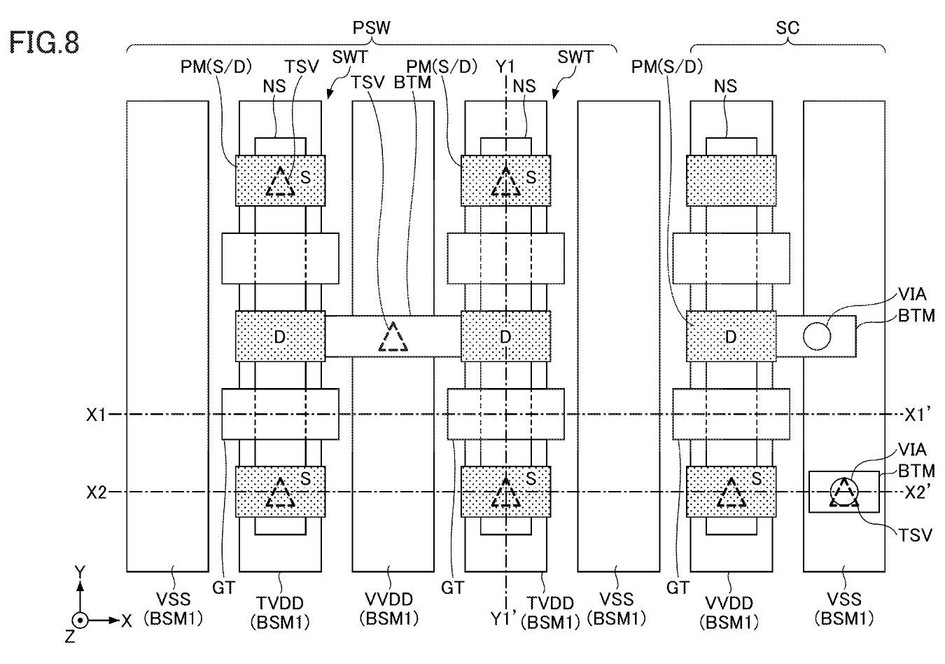

FIG. 8 shows an example of a plan view in which the power switch circuit PSW and the standard cell SC are viewed from the bottom wiring BTM side toward the substrate SUB side. In FIG. 8, the source S and drain D of the PMOS transistor PM, which are not designated by any of the symbols S and D, are in the open state and do not function as transistors.

The PMOS transistor PM of the switch transistor SWT of the power switch circuit PSW is arranged at a position overlapping with the power supply wiring TVDD of the BSM1 layer in a plan view. The PMOS transistor PM of the standard cell SC is arranged at a position overlapping with the virtual power supply wiring VVDD of the BSM1 layer in a plan view.

The source and drain of the PMOS transistor PM are arranged at positions corresponding to the formation region of the bottom wiring BTM in the Z-direction. The source and drain of the PMOS transistor PM are arranged on both sides in the Y-direction across the gate GT. The virtual power supply wiring VVDD of the BSM1 layer is arranged offset from the transistor row of the switch transistor SWT in a plan view.

In the power switch circuit PSW, the source S of the PMOS transistor PM is directly connected to the TSV. The TSV is connected to the power supply wiring TVDD of the BSM1 layer. The drain D of the PMOS transistor PM is connected to the virtual power supply wiring VVDD of the BSM1 layer via the bottom wiring BTM and the TSV. As shown in FIG. 8, when the switch transistor SWT includes a plurality of PMOS transistors PM, the drains D of the plurality of PMOS transistors PM may be connected to the virtual power supply wiring VVDD of the BSM1 layer via a common bottom wiring BTM. Thus, the number of bottom wirings BTM connected to the drains D of the PMOS transistors PM can be reduced.

The bottom wiring BTM connected to the drains D of the PMOS transistors PM is an example of a first wiring. The TSV connecting the bottom wiring BTM connected to the drains D of the PMOS transistors PM to the virtual power supply wiring VVDD of the BSM1 layer is an example of a second via.

When an inverter is formed in the standard cell SC, the source S of the PMOS transistors PM is connected to the virtual power supply wiring VVDD of the BSM1 layer via the TSV. The drain D of the PMOS transistor PM of the inverter is connected to the drain D of the NMOS transistor NM and the output signal wiring OUT of FIG. 7 via the bottom wiring BTM and the via VIA.

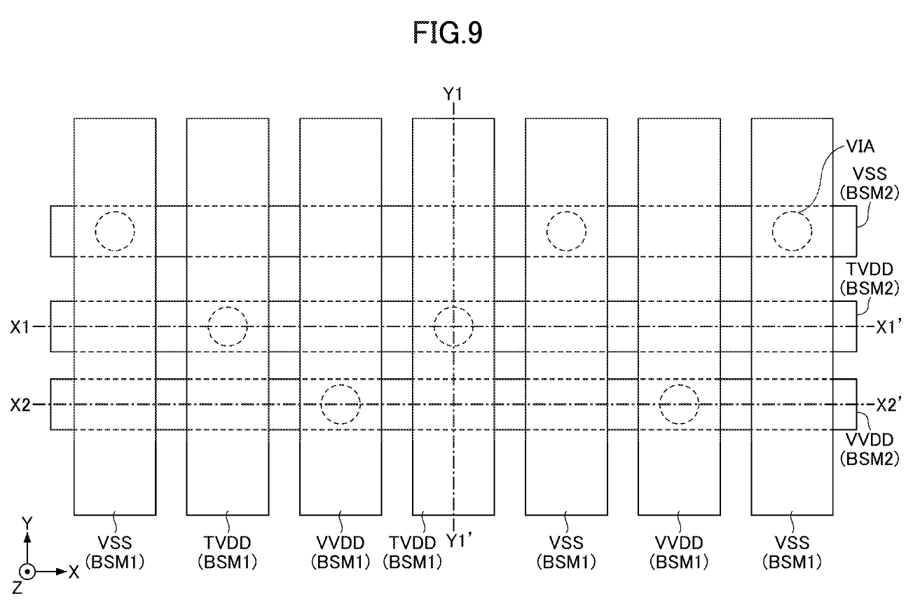

FIG. 9 shows an example of a plan view of the BSM1 layer and the BSM2 layer in a region where the power switch circuit PSW and the standard cell SC are formed. The wiring of the BSM1 layer extends in the Y-direction and is arranged at intervals in the X-direction. The wiring of the BSM2 layer extends in the X-direction and is arranged at intervals in the Y-direction.

In the BSM1 layer and the BSM2 layer, the same type of wiring (for example, the virtual power supply wiring VVDD) is connected to each other via the via VIA. Note that the virtual power supply wiring VVDD of the BSM1 layer provided in the region of the power switch circuit PSW shown in FIG. 8 is connected to the virtual power supply wiring VVDD of the BSM1 layer provided in the region of the standard cell SC via the virtual power supply wiring VVDD of the BSM2 layer.

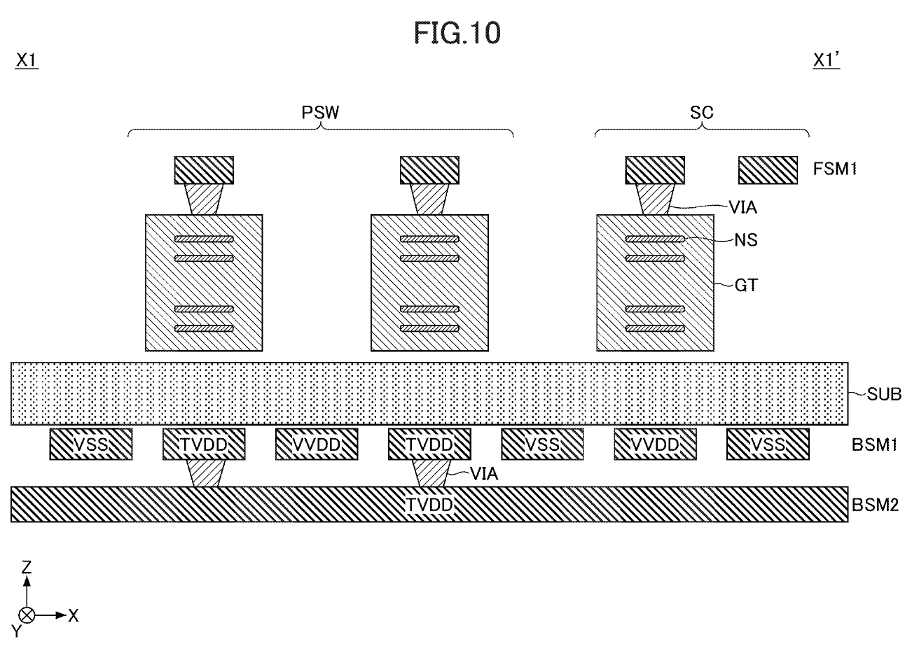

FIG. 10 shows an example of a cross section taken along a line X1-X1' of FIGS. 7 to 9. The gate GT of each transistor is connected to the wiring of the FSM1 layer via the via VIA. The nanosheet NS is provided through the gate GT. The gate GT is arranged on the substrate SUB via an insulating film. The wiring of the BSM1 layer is disposed below the substrate SUB via an insulating film.

The wirings of the BSM1 layer and the BSM2 layer, vias VIA, and the like below the substrate SUB may be formed below the substrate SUB where the power switch circuit PSW and the like are formed by using a semiconductor manufacturing process. Alternatively, the wirings of the BSM1 layer and the BSM2 layer, vias VIA, and the like below the substrate SUB may be formed on another substrate different from the substrate SUB on which the power switch circuit PSW and the standard cell SC are formed. In this case, a wiring layer including the wirings of the BSM1 layer and the BSM2 layer, vias VIA, and the like formed on another substrate is bonded to the lower side of the substrate SUB.

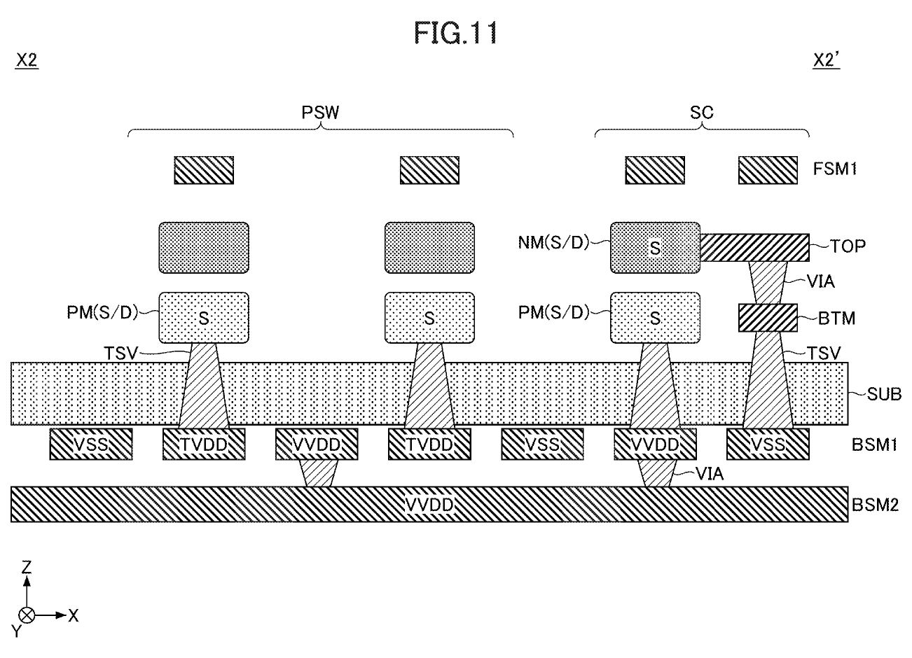

FIG. 11 shows an example of a cross section taken along a line X2-X2' of FIGS. 7 to 9. In the power switch circuit PSW, the source S and drain D of the NMOS transistor NM are set to the open state, and the source S of the PMOS transistor PM is directly connected to the TSV. The TSV is connected to the power supply wiring TVDD of the BSM1 layer.

In the standard cell SC, the source S of the NMOS transistor NM is connected to the ground wiring VSS of the BSM1 layer via the top wiring TOP, the via VIA, and the bottom wiring BTM, and TSV. The source S of the PMOS transistor PM is directly connected to the TSV. The TSV is connected to the virtual power supply wiring VVDD of the BSM1 layer.

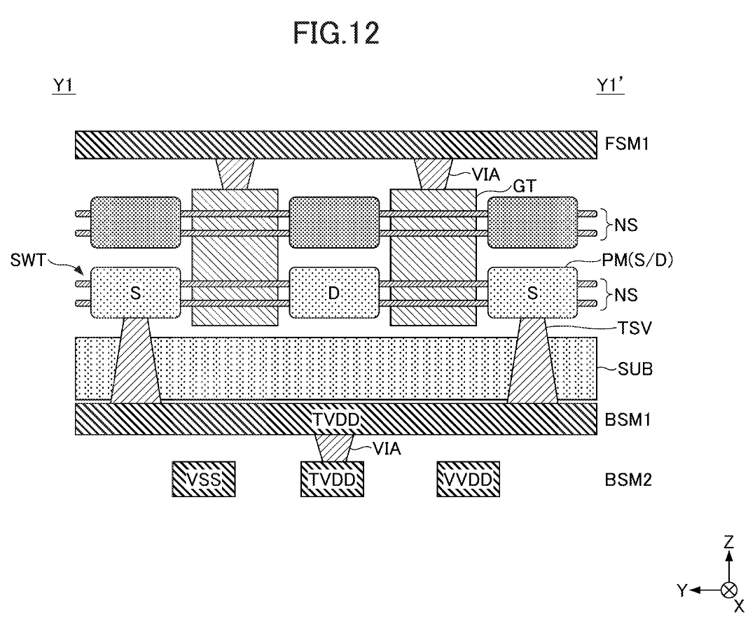

FIG. 12 shows an example of a cross section taken along a line Y1-Y1' of FIGS. 7 to 9. The source S and drain D of the NMOS transistor NM are in the open state and do not function as transistors. The source S of the PMOS transistor PM of the switch transistor SWT is directly connected to the TSV. The TSV is connected to the power supply wiring TVDD of the BSM1 layer. The top-side nanosheet NS is formed between the sources S and drain D of the NMOS transistor NM, and the bottom-side nanosheet NS is formed between the sources S and drain D of the PMOS transistor PM.

As described above, in the first embodiment, by connecting the source and drain of the CFET to the power supply wiring TVDD and the virtual power supply wiring VVDD formed on the back surface of the substrate SUB, the power switch circuit PSW using the CFET can be appropriately laid out. As a result, the power switch circuit PSW having a reduced circuit scale can be mounted on the semiconductor device 100.

### Second embodiment

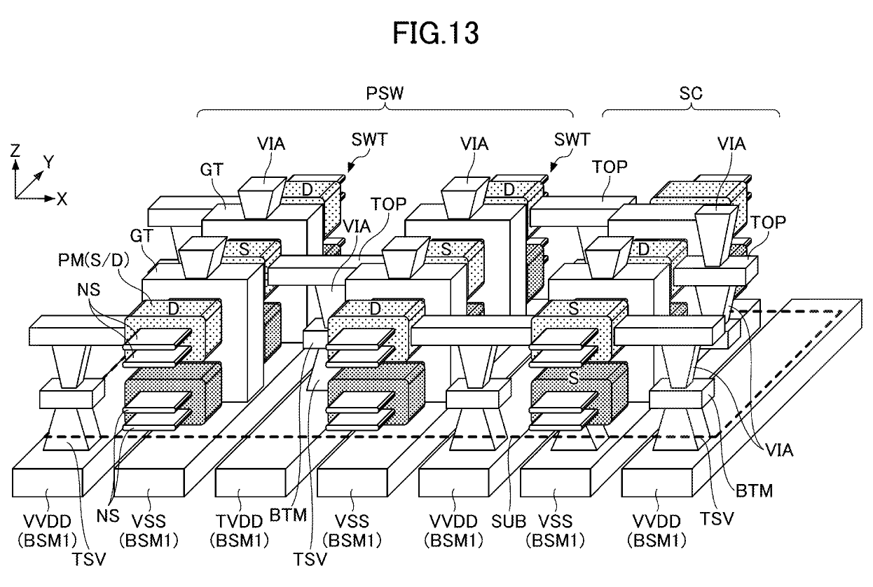

FIG. 13 shows an example of the layout of the power switch circuit and the standard cell in a second embodiment. Elements similar to those in FIG. 5 are denoted by the same signs, and detailed description thereof will be omitted. For example, the power switch circuit PSW and the standard cell SC shown in FIG. 13 are mounted on the standard cell block SCB of the semiconductor device 100 as in FIG. 1. The cross-sectional structure of the semiconductor device 100 on which the power switch circuit PSW and the standard cell SC shown in FIG. 13 are mounted is the same as in FIG. 2. The circuit arranged in the standard cell block SCB is the same as in FIG. 3. An example of the circuit of the power switch circuit PSW and the standard cell SC shown in FIG. 13 is the same as in FIG. 4.

FIG. 13 is different from the layout of FIG. 5 in that the positions of the PMOS transistor PM and the NMOS transistor NM in the Z-direction of each CFET are reversed from those of FIG. 5. That is, in FIG. 13, the source S and drain D of the PMOS transistor PM are formed in the semiconductor layer on the top side, and the source S and drain D of the NMOS transistor NM are formed in the semiconductor layer on the bottom side.

The drain D of the PMOS transistor PM of the power switch circuit PSW is connected to the virtual power supply wiring VVDD of the BSM1 layer via the top wiring TOP, the via VIA, and the bottom wiring BTM, and TSV. Similarly, the source S of the PMOS transistor PM of the power switch circuit PSW is connected to the power supply wiring TVDD of the BSM1 layer via the top wiring TOP, the via VIA, and the bottom wiring BTM, and TSV.

In the standard cell SC, the source S of the PMOS transistor PM is connected to the virtual power supply wiring VVDD of the BSM1 layer via the top wiring TOP, the via VIA, and the bottom wiring BTM, and TSV. In the standard cell SC, the source of the NMOS transistor NM is directly connected to the TSV. The TSV is connected to the ground wiring VSS of the BSM1 layer.

When the PMOS transistor PM is disposed on the top side and the NMOS transistor NM is disposed on the bottom side, the source and drain of the PMOS transistor PM cannot be connected to the wiring of the BSM1 layer by direct contact with the TSV. Furthermore, the power supply wiring TVDD of the BSM1 layer cannot be disposed under the column of the switch transistor SWT.

Therefore, in the power switch circuit PSW and the standard cell SC, the positions of the power supply wiring TVDD, the virtual power supply wiring VVDD, and the ground wiring VSS of the BSM1 layer are different from those in FIG. 5. Then, the source S and the drain D of the PMOS transistor PM are respectively connected to the power supply wiring TVDD and the virtual power supply wiring VVDD of the BSM1 layer after being drawn out in the X-direction by using the top wiring TOP.

In FIG. 13, the virtual power supply wiring VVDD of the BSM1 layer on the boundary with the standard cell SC is commonly connected to the power switch circuit PSW and the standard cell SC, but different virtual power supply wirings VVDD may be provided. In the power switch circuit PSW, the positions of the power supply wiring TVDD and the virtual power supply wiring VVDD of the BSM1 layer may be switched.

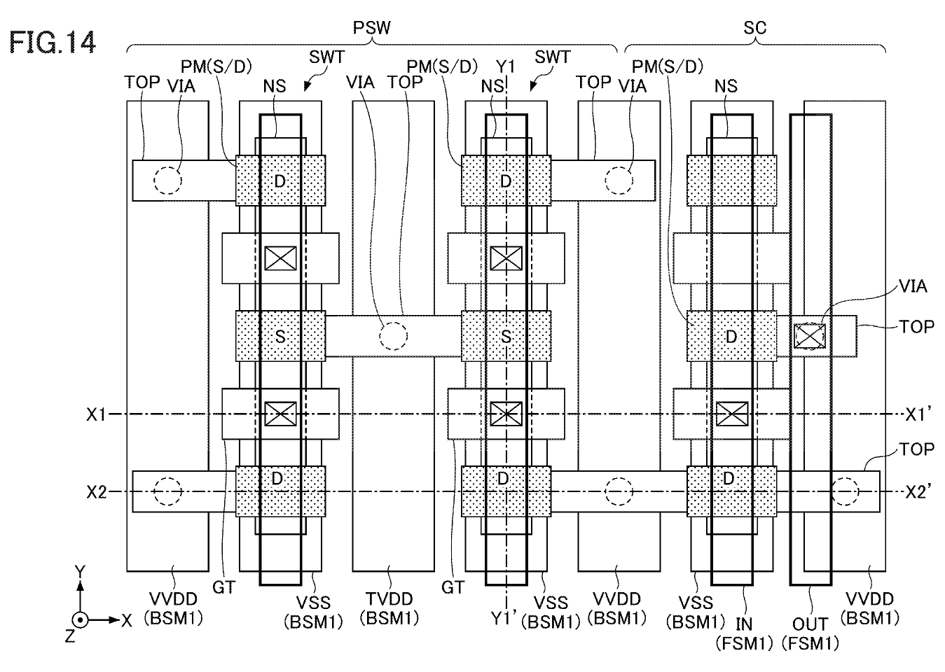

FIG. 14 shows an example of a plan view of the power switch circuit PSW and the standard cell SC of FIG. 13 when viewed from the top wiring TOP side toward the substrate SUB side. Elements similar to those in FIG. 7 are denoted by the same signs, and a detailed description thereof is omitted.

The switch transistor SWT of the power switch circuit PSW is arranged at a position overlapping with the ground wiring VSS of the BSM1 layer in a plan view. The drain D of the PMOS transistor PM of the switch transistor SWT is connected to the top wiring TOP extending on the virtual power supply wiring VVDD side of the BSM1 layer in a plan view, and is further connected to the via VIA connecting the top wiring TOP to the bottom wiring BTM. The source S of the PMOS transistor PM of the switch transistor SWT is connected to the top wiring TOP extending on the power supply wiring TVDD side of the BSM1 layer in a plan view, and is further connected to the via VIA connecting the top wiring TOP to the bottom wiring BTM.

The transistors of the standard cell SC are arranged at a position overlapping with the ground wiring VSS of the BSM1 layer in a plan view. When an inverter is formed in the standard cell SC, the source S of the PMOS transistor PM of the inverter is connected to the top wiring TOP extending on the virtual power supply wiring VVDD side of the BSM1 layer in a plan view. The drain D of the PMOS transistor PM of the inverter is connected to the output signal wiring OUT of the FSM1 layer via the top wiring TOP and the via VIA.

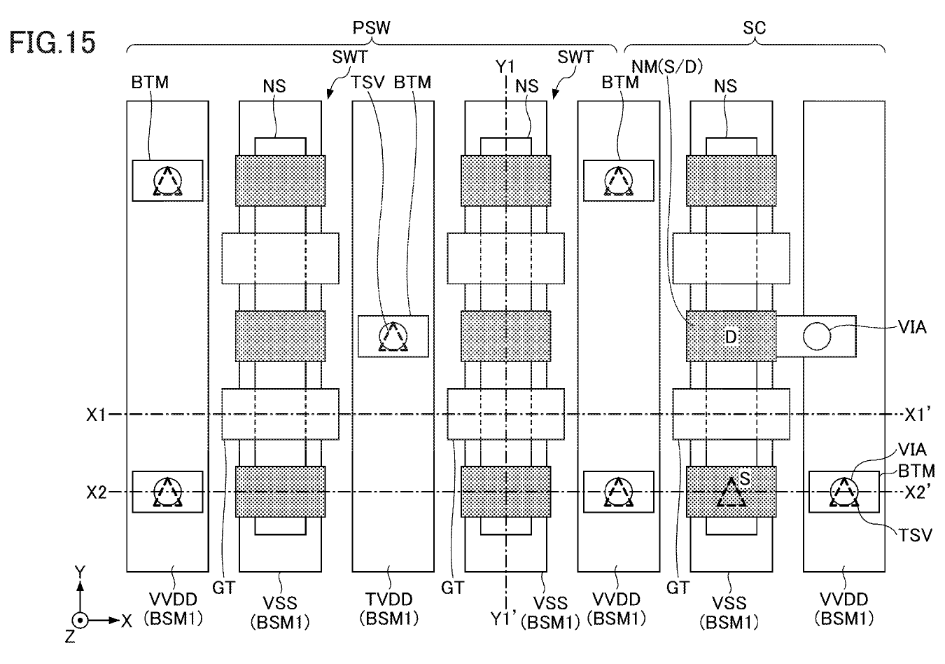

FIG. 15 shows an example of a plan view in which the power switch circuit PSW and the standard cell SC of FIG. 13 are viewed from the bottom wiring BTM side toward the substrate SUB side. Elements similar to those in FIG. 8 are denoted by the same signs, and a detailed description thereof is omitted.

In the power switch circuit PSW, the virtual power supply wiring VVDD of the BSM1 layer is connected to the bottom wiring BTM via the TSV, and the bottom wiring BTM is connected to the drain D of the PMOS transistor PM (see FIG. 14) via the via VIA and the top wiring TOP of FIG. 14.

In the standard cell SC, the source S of the NMOS transistor NM of the inverter is directly connected to the TSV. The TSV is connected to the ground wiring VSS of the BSM1 layer. The drain D of the NMOS transistor NM of the inverter is connected to the top wiring TOP (see FIG. 14) to which the drain D of the PMOS transistor PM of FIG. 14 is connected via the bottom wiring BTM and the via VIA. In the standard cell SC, the virtual power supply wiring VVDD of the BSM1 layer is connected to the top wiring TOP of FIG. 14 via the TSV, the bottom wiring BTM and the via VIA, and is connected to the source S of the PMOS transistor PM (see FIG. 14).

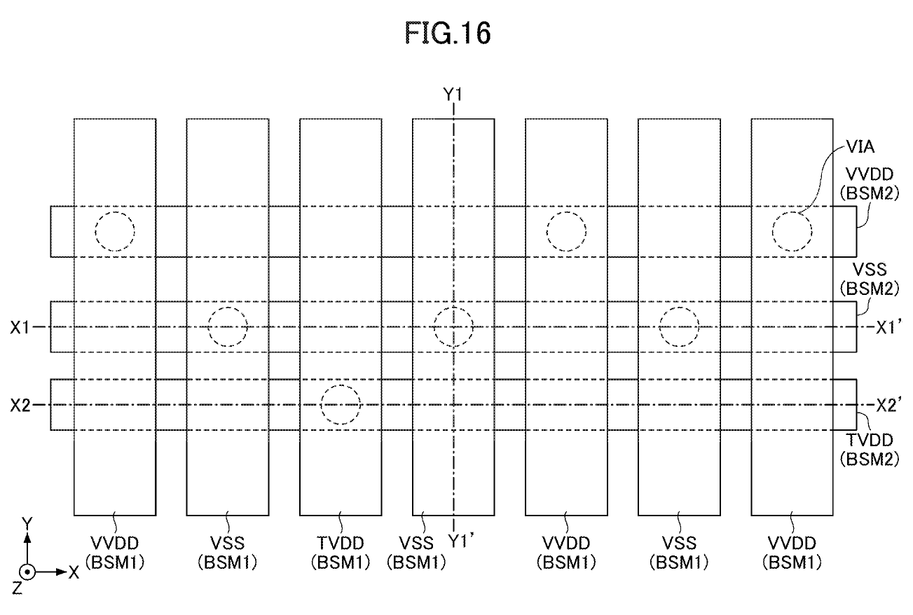

FIG. 16 shows an example of a plan view of the BSM1 layer and the BSM2 layer in a region where the power switch circuit PSW and the standard cell SC of FIG. 13 are formed. Elements similar to those of FIG. 9 are denoted by the same signs and detailed description thereof is omitted. In FIG. 16, also in the BSM1 layer and the BSM2 layer, wirings of the same type (for example, the virtual power wirings VVDD) are connected to each other via VIAs.

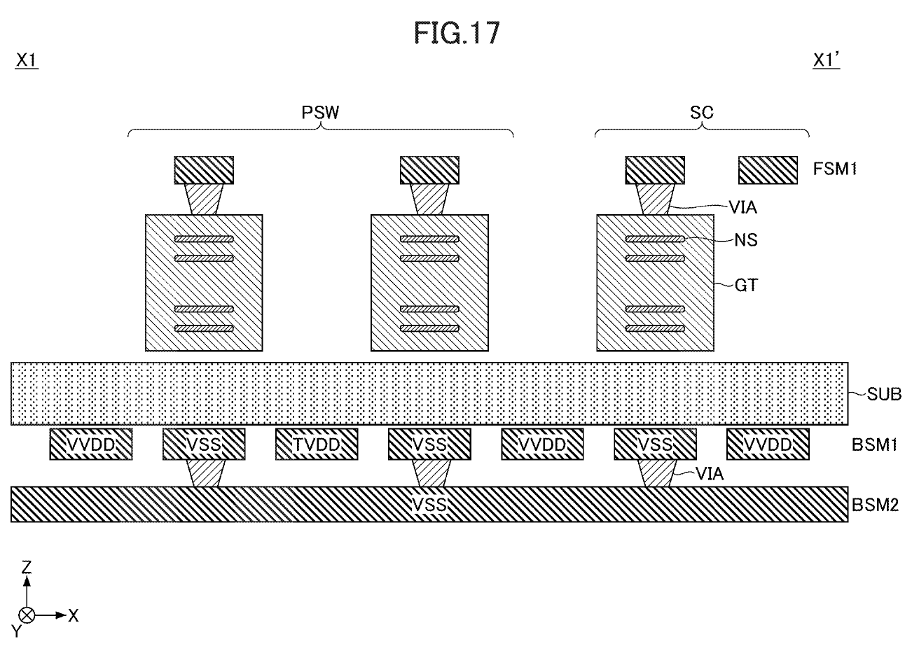

FIG. 17 shows an example of a cross section taken along the line X1-X1' of FIGS. 14 to 16. Elements similar to those of FIG. 10 are denoted by the same signs and detailed description thereof is omitted. FIG. 17 is the same as that of FIG. 10 except that the order of the virtual power supply wiring VVDD, the power supply wiring TVDD, and the ground wiring VSS arranged in the virtual power supply wiring VVDD of the BSM1 layer is different from that of FIG. 10 and the ground wiring VSS is formed in the BSM2 layer.

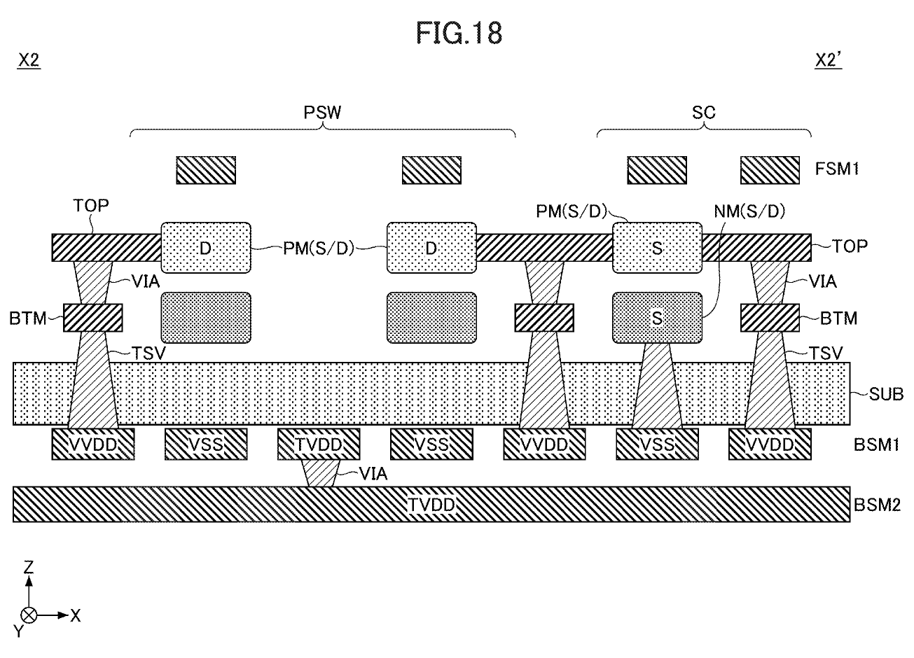

FIG. 18 shows an example of a cross section taken along the line X2-X2' of FIGS. 14 to 16. Elements similar to those in FIG. 11 are denoted by the same signs and detailed description thereof is omitted. In FIG. 18, the positions of the NMOS transistor NM and the PMOS transistor PM in the Z-direction are opposite to those in FIG. 11. Therefore, the drain D of the PMOS transistor PM of the power switch circuit PSW and the virtual power supply wiring VVDD of the BSM1 layer are electrically connected via the top wiring TOP, the via VIA, and the bottom wiring BTM, and TSV. Furthermore, the source S of the PMOS transistor PM of the standard cell SC and the virtual power supply wiring VVDD of the BSM1 layer are electrically connected via the top wiring TOP, the via VIA, and the bottom wiring BTM and TSV.

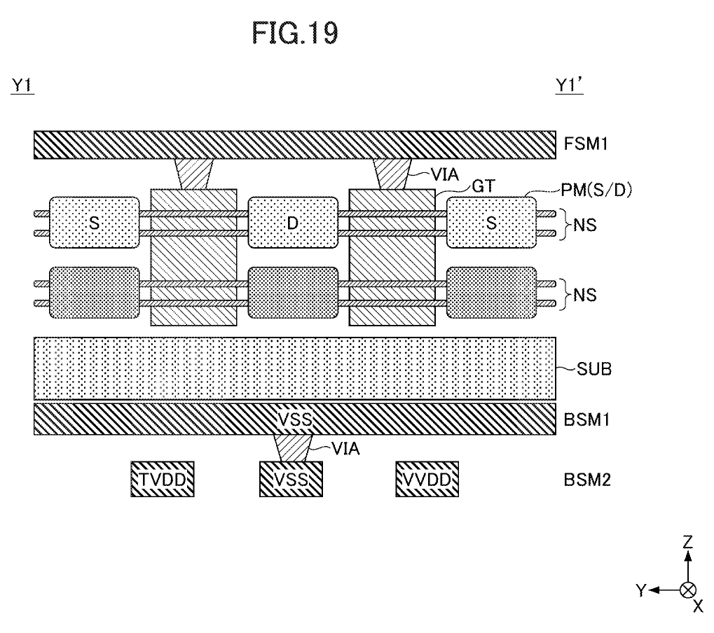

FIG. 19 shows an example of a cross section taken along the line Y1-Y1' of FIGS. 14 to 16. Elements similar to those in FIG. 12 are denoted by the same signs and detailed description thereof is omitted. FIG. 19 is the same as FIG. 12 except that the positions of the NMOS transistor NM and the PMOS transistor PM in the Z-direction are opposite to those in FIG. 12.

As described above, in the second embodiment, as in the first embodiment, by connecting the source and drain of the CFET to the power supply wiring TVDD and the virtual power supply wiring VVDD formed on the back surface of the substrate SUB, the power switch circuit PSW using the CFET can be appropriately laid out. As a result, the power switch circuit PSW having a reduced circuit scale can be mounted on the semiconductor device 100.

Note that the first and second embodiments described above show an example of a layout in which a circuit such as an inverter of the standard cell SC is connected to the virtual power supply wiring VVDD and the ground wiring VSS, and the power switch circuit PSW generates the virtual power supply potential VVDD. However, another example may be applied to a layout in which a circuit such as an inverter of the standard cell SC is connected to a power supply wiring VDD and a virtual ground wiring VVSS, and the power switch circuit PSW generates the virtual ground potential VVSS.

In this case, the switch transistor SWT of the power switch circuit PSW may include the NMOS transistor NM for connecting the ground wiring VSS to the virtual ground wiring VVSS, and the PMOS transistor PM in which the source S and drain D are set in the open state. The switch transistor SWT may be formed only by the NMOS transistor NM, and the PMOS transistor PM may not be formed.

According to the disclosed technique, a power switch circuit formed by using a CFET whose source and drain are directly connected to a TSV can be appropriately laid out.

Although the present invention has been described based on various embodiments, the present invention is not limited to the requirements shown in the above embodiments. These points may be changed to the extent that the object of the present invention is not lost, and may be appropriately defined according to the application mode.

What is claimed is:

1. A semiconductor device comprising:
a substrate;
a first power supply wiring and a second power supply wiring formed on a first surface of the substrate;
a first semiconductor layer formed above a second surface of the substrate opposite the first surface and electrically connected to the first power supply wiring;
a second semiconductor layer formed above the second surface of the substrate and electrically connected to the second power supply wiring;
a third semiconductor layer formed at a position overlapping with the first semiconductor layer in a plan view;
a fourth semiconductor layer formed at a position overlapping with the second semiconductor layer in a plan view;
a first gate formed on the substrate between the first semiconductor layer and the second semiconductor layer and between the third semiconductor layer and the fourth semiconductor layer; and
a transistor including the first semiconductor layer, the second semiconductor layer, and the first gate.

2. The semiconductor device according to claim 1, wherein
the third semiconductor layer and the fourth semiconductor layer are formed above the first semiconductor layer and the second semiconductor layer, and
the first semiconductor layer is connected to the first power supply wiring via a first via formed in the substrate.

3. The semiconductor device according to claim 2, wherein
the second power supply wiring is arranged offset from the transistor in a plan view.

4. The semiconductor device according to claim 3, further comprising:
a first wiring connected to the second semiconductor layer of the transistor;
and
a second via formed in the substrate for connecting the first wiring and the second power supply wiring.

5. The semiconductor device according to claim 4, further comprising:
a plurality of transistors, each of the plurality of transistors being the transistor, wherein
the first wiring is commonly connected to the second semiconductor layer of the plurality of transistors.

6. The semiconductor device according to claim 1, wherein
the first semiconductor layer and the second semiconductor layer are formed above the third semiconductor layer and the fourth semiconductor layer;
the first semiconductor layer is electrically connected to the first power supply wiring via a wiring and a via, and
the second semiconductor layer is electrically connected to the second power supply wiring via a wiring and a via.

7. The semiconductor device according to claim 1, wherein
a conductivity type of the first semiconductor layer and the second semiconductor layer is different from a conductivity type of the third semiconductor layer and the fourth semiconductor layer.
